(19) United States
(12) Patent Application Publication
(10) Pub. No.: US 2018/0181169 A1
(43) Pub. Date: Jun. 28, 2018

(54) COOLING DEVICE FOR CASE, COOLING ASSEMBLY FOR CASE, AND COOLING METHOD FOR CASE

(71) Applicants: CHENG-CHING SHENG, Taoyuan City (TW); JYNN-YU WANG, Taoyuan City (TW); TE-YANG CHEN, New Taipei City (TW); WEN-CHIN SUNG, Taipei City (TW)

(72) Inventors: CHENG-CHING SHENG, Taoyuan City (TW); JYNN-YU WANG, Taoyuan City (TW); TE-YANG CHEN, New Taipei City (TW); WEN-CHIN SUNG, Taipei City (TW)

(21) Appl. No.: 15/391,400

(22) Filed: Dec. 27, 2016

(51) Int. Cl. G06F 1/20; H05K 7/20

(52) U.S. Cl. CPC G06F 1/20; H05K 7/20181; H05K 7/20145

(57) ABSTRACT

A cooling device for a case has a case and an air cooling box mounted inside of the case. An air inlet and an air outlet are respectively mounted on two opposite side walls of the air cooling box, and the air inlet is larger than the air outlet in area. A compression region is disposed in the air cooling box, and communicates with the air inlet and the air outlet. The cooling device can lower the temperature of the air out of the air cooling box via the different areas of the air outlet and the air inlet. External air must pass through the air cooling box to enter the case, and the air outlet is smaller than the air inlet, such that most of the dust is gathered and accumulates in the air cooling box, facilitating ease in cleaning.

### BACKGROUND OF THE INVENTION

### 1. Field of the Invention

The present invention relates to a cooling device for a case, a cooling assembly for a case, and a cooling method for a case, and especially for an industrial chassis, such as a computer case.

### 2. Description of the Prior Arts

Conventionally, there are two ways of heat dissipation for an industrial chassis, such as a computer case: by conduction and by air cooling. Dissipation by conduction means transferring the heat inside the chassis to outside via heat conductive metal, such as cooper. The air cooling is commonly used in a computer case, and leads the external lower-temperature air to flow into the case via a fan, thereby processing heat-exchange to the air inside the case to achieve the cooling.

However, since the air drawing capability of the fan is limited, the cooling effect of the air cooling may be insufficient when the temperature in the industry chassis is too high. In addition, the fan must be mounted on an air inlet, and thus the fan draws not only the air but also the dust into the case from the air inlet. Therefore, after use for a period of time, the interior of the case may be filled with dust, which becomes a burden for the user to clean the case.

To overcome the shortcomings, the present invention provides a cooling device for a case, a cooling assembly for a case, and a cooling method for a case to mitigate or obviate the aforementioned problems.

### SUMMARY OF THE INVENTION

The main objective of the present invention is to provide a cooling device for a case, a cooling assembly for a case, and a cooling method for a case that can raise the cooling efficiency and accumulate the dust in a specific place to facilitate ease in cleaning.

The cooling method for a case comprises steps of:
(a) drawing external air, wherein external cold air is drawn into an air cooling box, which is mounted in an inner space of a case and has an air inlet and an air outlet, and the air inlet is larger than the air outlet in area;
(b) forming positive pressure and negative pressure, wherein the air is compressed in the air cooling box since an amount of an air flow entering the air inlet is larger than an amount of an air flow discharging from the air outlet, such that a positive pressure region is formed in the air cooling box, and a negative pressure region is formed in the case; and
(c) cooling the air, wherein the compressed air is released into the inner space of the case, thereby lowering a temperature of the inner space.

The cooling device for a case comprises:
a case being hollow, and having
   an inner space; and
   a first inlet and a first outlet respectively mounted on two different side walls of the case; and
an air cooling box mounted in the inner space of the case, and having
   an air inlet and an air outlet respectively mounted on two opposite side walls of the air cooling box; the air inlet corresponding in position to the first inlet of the case; the air inlet larger than the air outlet in area; and
   a compression region disposed in the air cooling box, and communicating with the air inlet and the air outlet.

The cooling assembly for a case comprises:
the aforementioned cooling device;
an air drawing assembly having
   an air drawing filter mounted on an outer wall of the case, and corresponding in position to the first inlet; and
   an air drawing device mounted in the inner space of the case, and mounted between the air inlet and the first inlet; and
an air discharging assembly having
   an air discharging filter mounted on the outer wall of the case, and corresponding in position to the first outlet; and
   an air discharging device mounted in the inner space of the case, and mounted on the first outlet.

By the Joule-Thomson Effect, when the external air is drawn into the air cooling box, the air staying and accumulating in the air cooling box is compressed since the air inlet is larger than the air outlet in area. Therefore, a positive-pressure region is formed in the air cooling box, and a negative-pressure region is formed in the case. As a result, when the compressed air enters the negative-pressure region, the air is expanded and lowers the temperature, thereby cooling the inner space of the case in the negative-pressure region.

In addition, when the air with relatively high pressure enters the inner space of the case from the air cooling box, the pressure is lowered to expand the air, and thus lowers the temperature by 5 to 8 degrees Celsius.

Furthermore, besides lowering the temperature of the blown-out air via the air cooling box with the air inlet and the air outlet of different areas, the present invention also has an advantage that gathering most of the dust in the air cooling box since the external air must pass through the air cooling box to enter the inner space of the case, and the air outlet is small in inner diameter. Therefore, the region to be cleaned is narrowed, thereby facilitating ease in cleaning.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a cooling assembly for a case in accordance with the present invention;

FIG. 2 is an exploded perspective view of the cooling assembly for a case in FIG. 1;

FIG. 3 is a front view in partial section of the cooling assembly for a case in FIG. 1;

FIG. 4 is a top view in partial section of the cooling assembly for a case in FIG. 1;

FIG. 5 is an exploded perspective view of an air cooling box and an air drawing device of the cooling assembly for a case in FIG. 1; and

FIG. 6 is a first flow chart of a cooling method for a case in accordance with the present invention.

### DETAILED DESCRIPTION OF THE PREFERRED EMBODIMENTS

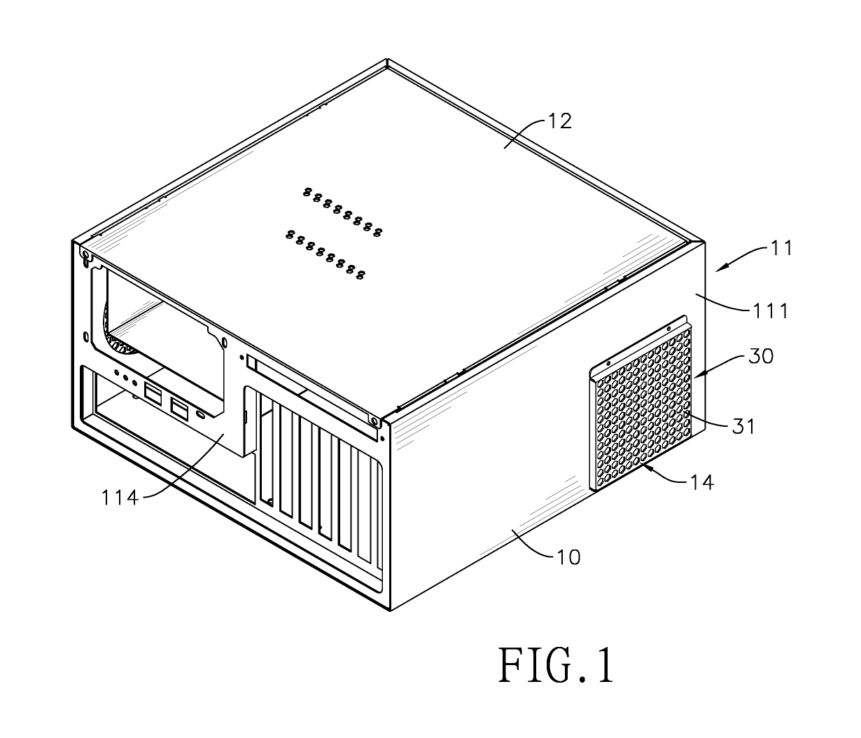

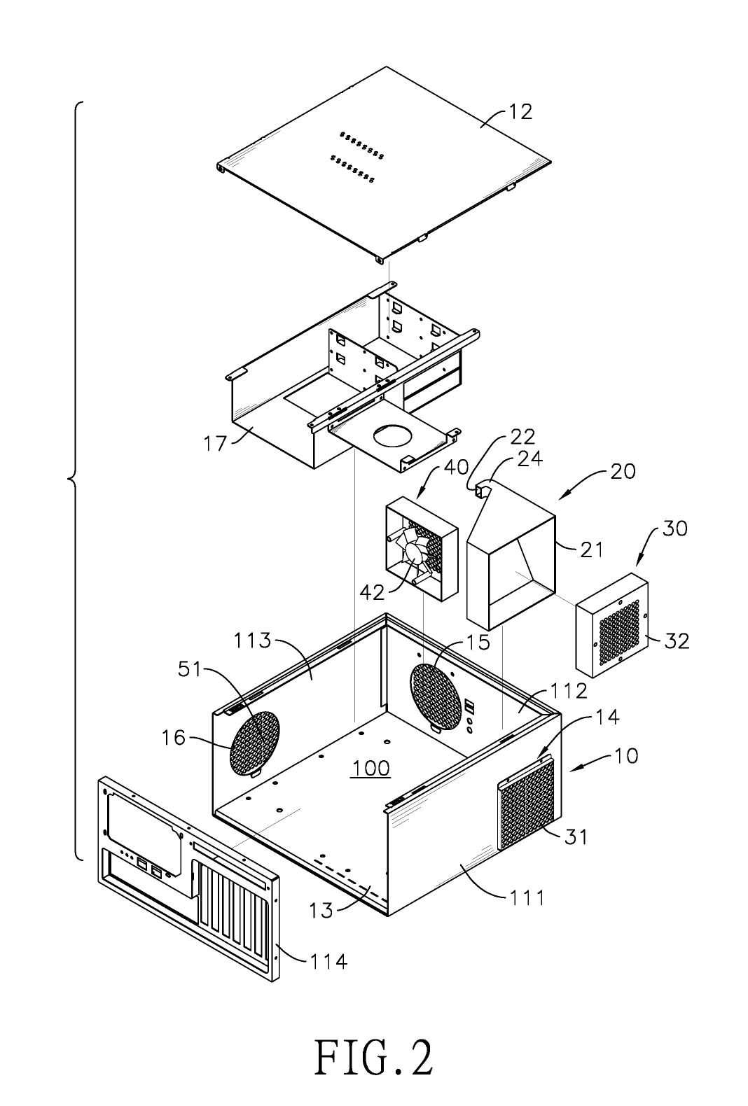

With reference to FIGS. 1 and 2, a cooling assembly for a case in accordance with the present invention comprises a cooling device, an air drawing assembly 30, and an air discharging assembly 40. The cooling device comprises a case 10 and an air cooling box 20.

The case 10 is hollow, and has an inner space 100, multiple side walls 11, a first outer wall 12, a second outer wall 13, a first inlet 14, a first outlet 15, a second outlet 16, and a cooling part 17.

With reference to FIG. 2, the side walls 11 are connected to each other and form a loop. The side walls 11, the first outer wall 12 and the second outer wall 13 together form the inner space 100. In a preferred embodiment, the case 10 is rectangular, and the side walls 11 include a first side wall 111, a second side wall 112, a third side wall 113, and a fourth side wall 114. The first outer wall 12 becomes a top of the case 10, and the second outer wall 13 becomes a bottom of the case 10. But the shape and structure of the case 10 are by no means limited to the abovementioned.

The first inlet 14 and the first outlet 15 are respectively mounted on two different side walls 11 of the case 10. In a preferred embodiment, the first inlet 14 is mounted on the first side wall 111, and is disposed adjacent to the second side wall 112. The first outlet 15 is mounted on the second side wall 112, and is disposed adjacent to the third side wall 113. But the positions of the first inlet 14 and the first outlet 15 are by no means limited to the abovementioned, as long as there is a sufficient distance between the first inlet 14 and the first outlet 15. The second outlet 16 is mounted on the third side wall 113, and is disposed adjacent to the fourth side wall 114. The cooling part 17 is mounted in the inner space 100 of the case 10, is mounted between the third side wall 113 and the fourth side wall 114, and is disposed adjacent to the second outlet 16. In a preferred embodiment, the cooling part 17 is a frame for mounting computer components, such as a CPU (Central Processing Unit). But in another preferred embodiment, the cooling part 17 may be a space, rather than a frame, for accommodating the computer components therein.

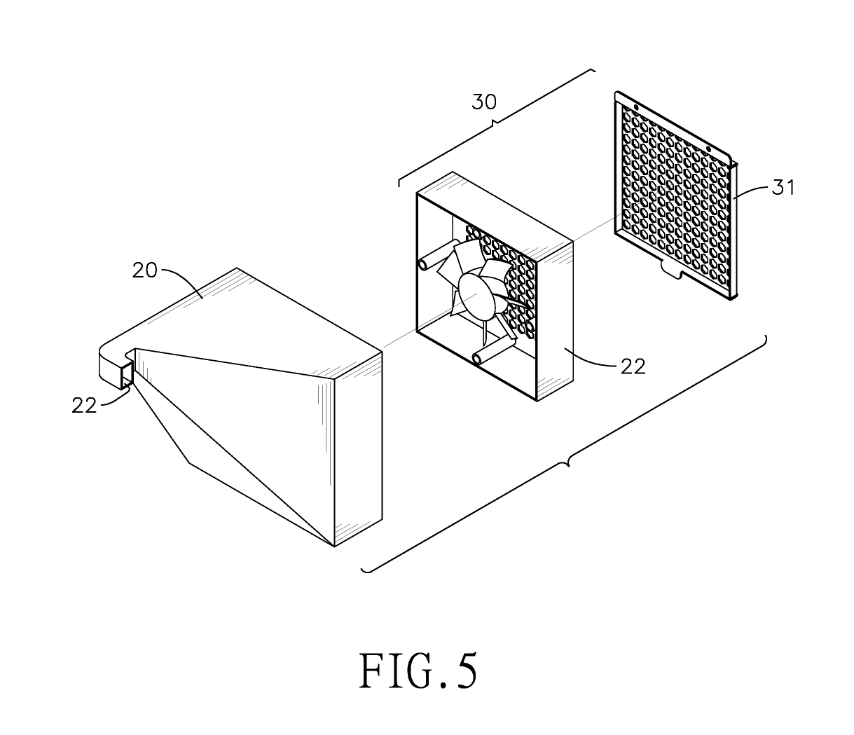

With reference to FIGS. 2, 4, and 5, the air cooling box 20 is mounted in the inner space 100 of the case 10. The air cooling box 20 and the cooling part 17 are disposed diagonally opposite each other. In a preferred embodiment, the air cooling box 20 is mounted between the first side wall 111 and the second side wall 112. The cooling box 20 has an air inlet 21, an air outlet 22, a compression region 23, and a curved tube 24. The air inlet 21 and the air outlet 22 are respectively mounted on two opposite ends of the cooling box 20, and communicate with an interior of the cooling box 20. The air inlet 21 is larger than the air outlet 22 in area. The air inlet 21 corresponds in position to the first inlet 14 of the case 10, and the air inlet 21 completely covers the first inlet 14. In other words, when external air enters the first inlet 14, the air must pass through the air inlet 21 and the air outlet 22 first, and then enters the inner space 100 of the case 10.

In a preferred embodiment, an area ratio of the air inlet 21 to the air outlet 22 is preferably, but not limited to, from 30:1 to 50:1.

In a preferred embodiment, an area of the air cooling box 20 gradually decreases from the air inlet 21 to the air outlet 22. But the shape of the air cooling box 20 is by no means limited to the abovementioned.

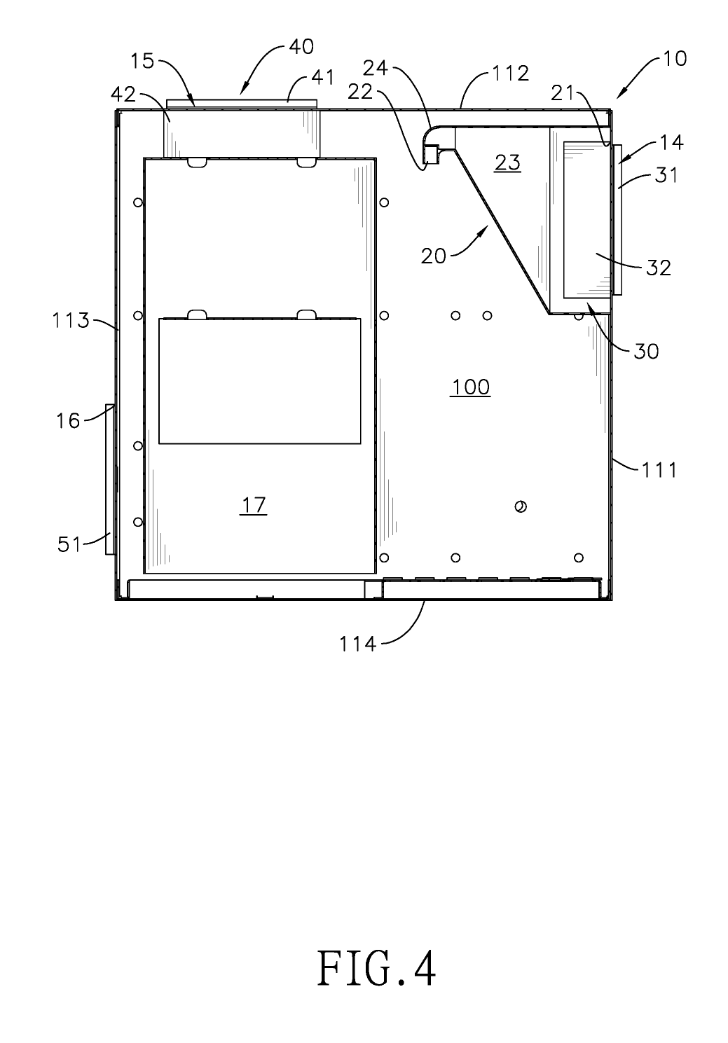

With reference to FIG. 4, the compression region 23 is disposed in the air cooling box 20, and is a gradually narrowed space connected between and communicating with the air inlet 21 and the air outlet 22. The air outlet 22 faces toward the cooling part 17, and the air outlet 22 is lower than the cooling part 17 in height position. The curved tube 24 is mounted between the compression region 23 and the air outlet 22. To be specific, one end of the curved tube 24 is connected to the air outlet 22, and another end of the curved tube 24 is connected to the compression region 23. In a preferred embodiment, the curved tube 24 is bent at 90 degrees to make the air outlet 22 face to the fourth side wall 114.

With reference to FIG. 2, the air drawing assembly 30 is mounted between the air inlet 21 and the first inlet 14, and corresponds to the air inlet 21 and the first inlet 14 in size and shape. The air drawing assembly 30 has an air drawing filter 31 and an air drawing device 32. The air drawing filter 31 is mounted on an outer wall of the case 10, and to be specific, is mounted on an outer surface of the first side wall 111. The air drawing filter 31 corresponds in position to the first inlet 14. The air drawing device 32 is mounted in the inner space 100 of the case 10, and is mounted between the air inlet 21 and the first inlet 14. In a preferred embodiment, the air drawing device 32 is, but not limited to, a fan for drawing air. In the first inlet 14, an entering route of external air comprises, in sequence, the air drawing filter 31, the first inlet 14, the air drawing device 32, and the air inlet 21.

The air discharging assembly 40 is mounted on the first outlet 15, and corresponds to the first outlet 15 in size and shape. The air discharging assembly 40 has an air discharging filter 41 and an air discharging device 42. The air discharging filter 41 is mounted on the outer wall of the case 10, and to be specific, is mounted on an outer surface of the second side wall 112. The air discharging filter 41 corresponds in position to the first outlet 15. The air discharging device 42 is mounted in the inner space 100 of the case 10, and is mounted on an inner wall of the first outlet 15. In a preferred embodiment, the air discharging device 42 is, but not limited to, a fan for discharging air.

In a preferred embodiment, a second outlet filter 51 is mounted on an outer surface of the third side wall 113, and corresponds to the second outlet 16 in position, size and shape.

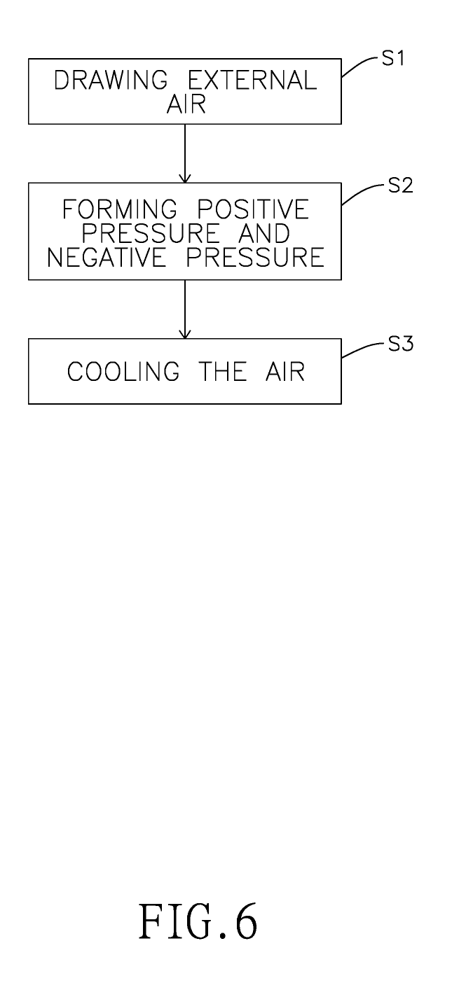

With reference to FIG. 6, a cooling method for a case in accordance with the present invention is preferably used in, but not limited to, the cooling assembly mentioned above. The cooling method comprises the following steps:

The first step (S1) is to draw external air. External cold air is drawn into an air cooling box 20 via a route through, in sequence, the air drawing filter 31, the air drawing device 32 and the air inlet 21 by the air drawing device 32 (fan). Then, the air stays and accumulates in the compression region 23 of the air cooling box 20.

The second step (S2) is to form positive pressure and negative pressure. The air is compressed in the compression region 23 of the air cooling box 20 since an amount of an air flow entering the air inlet 21 is larger than an amount of an air flow discharging from the air outlet 22, which is due to the relatively larger air inlet 21 and the relatively smaller air outlet 22. Therefore, a positive pressure region is formed in the compression region 23 of the air cooling box 20. A negative pressure region is formed as well in the inner space 100 of the case 10 since the flowing direction of the air is toward the inner space 100.

The third step (S3) is to cool the air. The air in the compression region 23 is compressed to reduce the volume, such that the compressed air suddenly expands when the compressed air discharges to the inner space 100 of the case 10. According to the Joule-Thomson Effect, when the volume suddenly increases, the temperature of the air is lowered accordingly. Thus, the air entering the inner space 100 has the function of cooling. In a preferred embodiment, the area ratio of the air inlet 21 to the air outlet 22 makes the temperature in the inner space 100 of the case 10 drop by 5 to 8 degrees Celsius.

When the cooling assembly or the cooling method is in use, the heat mainly comes from the cooling part 17, which is for mounting electronic equipment that is prone to produce heat, such as a CPU or power supply. To increase the cooling efficiency and to avoid dust accumulation, the present invention also has the following features.

First, the external air must pass through the air inlet 21 and air outlet 22 to enter the case 10, and the air inlet 21 is larger than the air outlet 22 in area, such that most of the dust is gathered and accumulates in the air cooling box 20 and does not enter the case 10, thereby facilitating ease in cleaning.

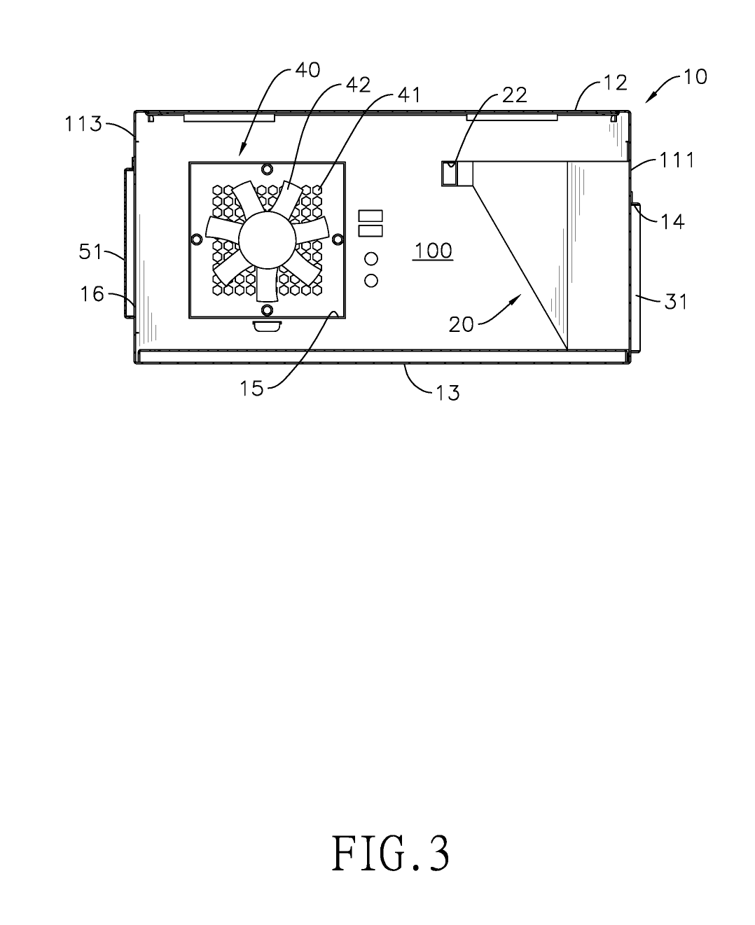

Second, with reference to FIG. 3, the air cooling box 20 is located near the second outer wall 13, and the cooling part 17 is located near the first outer wall 12. Therefore, even though the dust enters the inner space 100 of the case 10, the dust will drop and accumulate on the bottom (second outer wall 13) and will not accumulate on the cooling part 17 and the electronic equipment, which are in a relatively higher place.

Third, with reference to FIGS. 2 and 4, temperatures of the side walls may be easily raised when the electronic equipment is working. At this time, the curved tube 24 prevents the air out of the air inlet 22 from flowing toward the heated second side wall 112 and the third side wall 113 directly, such that the air will not be heated by the side walls 11, which lowers the cooling efficiency.

To sum up, the main advantages of the present invention is to lower the temperature of the air out of the air cooling box 20 via the different areas of the air outlet 22 and the air inlet 21. In addition, the external air must pass through the air cooling box 20 to enter the case 10, and the air outlet 22 is smaller than the air inlet 21, such that most of the dust is gathered and accumulates in the air cooling box 20. Therefore, the region to be cleaned is narrowed, thereby facilitating ease in cleaning.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A cooling method for a case, the cooling method comprising steps of:
(a) drawing external air, wherein external cold air is drawn into an air cooling box, which is mounted in an inner space of a case and has an air inlet and an air outlet, and the air inlet is larger than the air outlet in area;
(b) forming positive pressure and negative pressure, wherein the air is compressed in the air cooling box since an amount of an air flow entering the air inlet is larger than an amount of an air flow discharging from the air outlet, such that a positive pressure region is formed in the air cooling box, and a negative pressure region is formed in the case; and
(c) cooling the air, wherein the compressed air is released into the inner space of the case, thereby lowering a temperature of the inner space.

2. The cooling method as claimed in claim 1, wherein in the step of cooling the air, the temperature of the inner space is lowered by 5 to 8 degrees Celsius.

3. A cooling device comprising:
a case being hollow, and having
an inner space; and
a first inlet and a first outlet respectively mounted on two different side walls of the case; and
an air cooling box mounted in the inner space of the case, and having an air inlet and an air outlet respectively mounted on two opposite side walls of the air cooling box; the air inlet corresponding in position to the first inlet of the case; the air inlet being larger than the air outlet in area; and
a compression region disposed in the air cooling box, and communicating with the air inlet and the air outlet.

4. The cooling device as claimed in claim 3, wherein an area of the air cooling box gradually decreases from the air inlet to the air outlet.

5. The cooling device as claimed in claim 3, wherein an area ratio of the air inlet to the air outlet is from 30:1 to 50:1.

6. The cooling device as claimed in claim 4, wherein an area ratio of the air inlet to the air outlet is from 30:1 to 50:1.

7. The cooling device as claimed in claim 3 further comprising a cooling part mounted in the case, wherein the cooling part and the air cooling box are disposed diagonally opposite each other; the air outlet faces toward the cooling part, and the air outlet is lower than the cooling part in height position.

8. The cooling device as claimed in claim 6 further comprising a cooling part mounted in the case, wherein the cooling part and the air cooling box are disposed diagonally opposite each other; the air outlet faces toward the cooling part, and the air outlet is lower than the cooling part in height position.

9. The cooling device as claimed in claim 3, wherein the air cooling box further has a curved tube; one end of the curved tube is connected to the air outlet, and another end of the curved tube is connected to the compression region.

10. The cooling device as claimed in claim 8, wherein the air cooling box further has a curved tube; one end of the curved tube is connected to the air outlet, and another end of the curved tube is connected to the compression region.

11. The cooling device as claimed in claim 3, wherein the case further has a second outlet mounted in the inner space; the first outlet and the second outlet are respectively mounted on two different side walls of the case.

12. The cooling device as claimed in claim 10, wherein the case further has a second outlet mounted in the inner space; the first outlet and the second outlet are respectively mounted on two different side walls of the case.

13. A cooling assembly with a cooling device as claimed in claim 3, the cooling assembly comprising:
an air drawing assembly having
an air drawing filter mounted on an outer wall of the case, and corresponding in position to the first inlet; and
an air drawing device mounted in the inner space of the case, and mounted between the air inlet and the first inlet; and
an air discharging assembly having
an air discharging filter mounted on the outer wall of the case, and corresponding in position to the first outlet; and
an air discharging device mounted in the inner space of the case, and mounted on the first outlet.

14. The cooling assembly as claimed in claim 13, wherein the air drawing device is a fan for drawing air, and the air discharging device is a fan for discharging air.
